(19) United States
(12) Patent Application Publication
(10) Pub. No.: US 2025/0364049 A1
(43) Pub. Date: Nov. 27, 2025

(54) VERTICAL NON-VOLATILE MEMORY DEVICE

(71) Applicant: Samsung Electronics Co., Ltd., Suwon-si (KR)

(72) Inventors: Seongjae Go, Suwon-si (KR); Duyoung Yang, Suwon-si (KR); Kangmin Kim, Suwon-si (KR)

(21) Appl. No.: 19/013,136

(22) Filed: Jan. 8, 2025

(30) Foreign Application Priority Data
May 27, 2024 (KR) 10-2024-0068884

(51) Int. Cl. G11C 16/04; G11C 5/06; H10B 41/10; H10B 41/27; H10B 41/35; H10B 43/10; H10B 43/27; H10B 43/35

(52) U.S. Cl. CPC G11C 16/0483; G11C 5/063; H10B 41/10; H10B 41/27; H10B 41/35; H10B 43/10; H10B 43/27; H10B 43/35

(57) ABSTRACT

A vertical non-volatile memory device includes a memory cell region and an extension region. The memory cell region includes a memory stack structure, and the memory stack structure includes first channel regions in channel holes, first gate dielectric layers that extend around respective ones of the first channel regions, and first gate lines that extend around respective ones of the first gate dielectric layers. The memory cell region and the extension region each include a string selection structure in an upper portion thereof, and the string selection structure includes second channel regions in string selection line holes, gate dielectric layers on upper surfaces and both side surfaces of the second channel regions, and second gate lines that extend around respective ones of the second gate dielectric layers.

### CROSS-REFERENCE TO RELATED APPLICATION

This application is based on and claims priority under 35 U.S.C. § 119 to Korean Patent Application No. 10-2024-0068884, filed on May 27, 2024, in the Korean Intellectual Property Office, the disclosure of which is incorporated by reference herein in its entirety.

### BACKGROUND

The inventive concept relates to a memory device, and more particularly, to a vertical non-volatile memory device.

In electronic systems that require data storage, semiconductor devices capable of storing large amounts of data are required. Accordingly, vertical non-volatile memory devices having three-dimensionally arranged memory cells instead of two-dimensionally arranged memory cells have been proposed. However, it may be difficult to reliably manufacture such vertical non-volatile memory devices having memory cells arranged three-dimensionally.

### SUMMARY

The inventive concept provides a vertical non-volatile memory device having reliable three-dimensional memory cells.

According to some embodiments of the inventive concept, there is provided a vertical non-volatile memory device including a memory cell region and an extension region adjacent to the memory cell region in a first direction.

The memory cell region includes a memory stack structure, and the memory stack structure includes a plurality of first channel regions in channel holes, such that the channel holes extend in a third direction and are spaced apart from each other in the first direction and a second direction,, such that the second direction and the third direction intersect the first direction, a plurality of first gate dielectric layers that extend around respective ones of the plurality of first channel regions in plan view, and a plurality of first gate lines that extend around respective ones of the plurality of first gate dielectric layers and are spaced apart from each other in the third direction.

The memory cell region and the extension region each include a string selection structure in an upper portion thereof, and the string selection structure includes a plurality of second channel regions in string selection line holes, wherein the string selection line holes extend in the third direction and are spaced apart from each other in the first and second directions, a plurality of second gate dielectric layers on upper surfaces and on both side surfaces of the plurality of second channel regions, and a plurality of second gate lines that extend around respective ones of the plurality of second gate dielectric layers in plan view and are spaced apart from each other in the second direction.

According to some embodiments of the inventive concept, there is provided a vertical non-volatile memory device including a memory cell region and an extension region adjacent to the memory cell region in a first direction.

The memory cell region includes a memory stack structure, and the memory stack structure includes a plurality of first channel regions in channel holes, wherein the channel holes extend in a third direction and are spaced apart from each other in the first direction and a second direction such that the second direction and the third direction intersect the first direction, a plurality of first gate dielectric layers that extend around respective ones of the plurality of first channel regions in plan view, and a plurality of first gate lines that extend around respective ones of the plurality of first gate dielectric layers and are spaced apart from each other in the third direction.

The memory cell region and the extension region each include a string selection structure in an upper portion thereof, and the string selection structure includes a plurality of second channel regions in string selection line holes. The string selection line holes extend in the third direction and are spaced apart from each other in the first and second directions, a plurality of second gate dielectric layers on upper surfaces and on both side surfaces of the plurality of second channel regions, and a plurality of second gate lines that extend around respective ones of the plurality of second gate dielectric layers in plan view and are spaced apart from each other in the second direction.

The plurality of first channel regions in the memory cell region are adjacent to respective ones of the plurality of second channel regions in the third direction, and a side surface of each of the second gate lines in the extension region is in contact with a respective one of a plurality of string selection line-conductive plugs.

According to some embodiments of the inventive concept, there is provided a vertical non-volatile memory device including a memory cell region and an extension region adjacent to the memory cell region in a first direction.

The memory cell region includes a memory stack structure, and the memory stack structure includes a plurality of first channel regions in channel holes, wherein the channel holes extend in a third direction and are spaced apart from each other in the first direction and a second direction such that the second direction and the third direction intersect the first direction, a plurality of first gate dielectric layers that extend around respective ones of the plurality of first channel regions in plan view, and a plurality of first gate lines that extend around respective ones of the plurality of first gate dielectric layers and are spaced apart from each other in the third direction.

The memory cell region and the extension region each include a string selection structure in an upper portion thereof, and the string selection structure includes string selection cylinder structures, a plurality of second gate dielectric layers on upper surfaces and both side surfaces of a plurality of second channel regions, and a plurality of second gate lines that extend around respective ones of the plurality of second gate dielectric layers in plan view and are spaced apart from each other in the second direction, and wherein the string selection cylinder structures include the plurality of second channel regions having cylinders and in string selection line holes, wherein the string selection line holes extend in the third direction and are spaced apart from each other in the first and second directions, buried insulating layers partially filling inner spaces of the cylinders of the plurality of second channel regions, and drain conductive layers on the buried insulating layers inside the cylinders.

The plurality of first channel regions in the memory cell region are electrically connected to respective ones of the plurality of second channel regions in the third direction, bit line-conductive plugs are on upper surfaces of respective ones of the drain conductive layers of the memory cell region, and a side surface of each of the second gate lines in the extension region is in contact with respective ones of a plurality of string selection line-conductive plugs.

### BRIEF DESCRIPTION OF THE DRAWINGS

Embodiments will be more clearly understood from the following detailed description taken in conjunction with the accompanying drawings in which:

FIG. 1 is a block diagram of a vertical non-volatile memory device according to some embodiments;

FIG. 2 is a schematic perspective view of a vertical non-volatile memory device according to some embodiments;

FIG. 3 is an equivalent circuit diagram of a memory cell array of a vertical non-volatile memory device according to some embodiments;

FIG. 4 is a schematic plan view of a vertical non-volatile memory device according to some embodiments;

FIG. 5 is a schematic plan view illustrating a memory cell region and an extension region of a vertical non-volatile memory device according to some embodiments;

FIGS. 6 to 9 are cross-sectional views illustrating a memory stack structure and a string selection structure in a memory cell region of a vertical non-volatile memory device according to some embodiments;

FIGS. 10 and 11 are cross-sectional views illustrating a memory stack structure and a string selection structure in an extension region of a vertical non-volatile memory device according to some embodiments; and

FIGS. 12 to 26 are cross-sectional views illustrating a method of manufacturing the memory stack structure and the string selection structure in the vertical non-volatile memory device of FIGS. 6 to 11.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted.

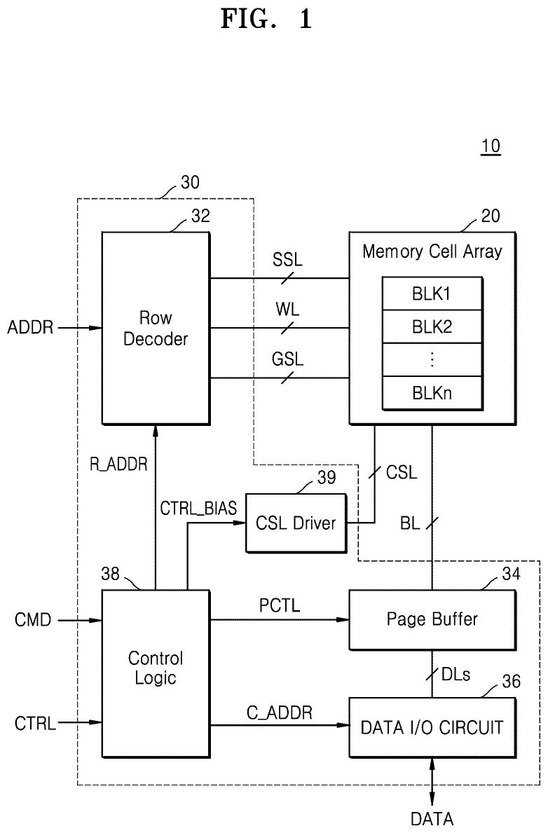

FIG. 1 is a block diagram of a vertical non-volatile memory device 10 according to some embodiments.

Specifically, the vertical non-volatile memory device 10 has characteristics of continuously maintaining stored data even when power is not supplied. The vertical non-volatile memory device 10 may include a vertical NOT-AND (NAND) flash memory device.

The vertical non-volatile memory device 10 may include a memory cell array 20 and a peripheral circuit 30. The memory cell array 20 includes a plurality of memory cell blocks BLK1, BLK2, . . . , and BLKn (n is a positive integer). Each of the plurality of memory cell blocks BLK1, BLK2, . . . , and BLKn (n is a positive integer) may include a plurality of memory cells. The memory cell blocks BLK1, BLK2, . . . , and BLKn (n is a positive integer) may be connected to the peripheral circuit 30 via a bit line BL, a word line WL, a string selection line SSL, and a ground selection line GSL.

The peripheral circuit 30 may include a row decoder 32, a page buffer 34, a data input/output (I/O) circuit 36, control logic 38, and a common source line driver 39. Although not shown in FIG. 1, the peripheral circuit 30 may further include various circuits, such as a voltage generation circuit for generating various voltages for the operation of the vertical non-volatile memory device 10, an error correction circuit for correcting errors in data read from the memory cell array 20, and an I/O interface.

The memory cell array 20 may be electrically connected to the page buffer 34 via the bit line BL. The memory cell array 20 may be electrically connected to the row decoder 32 via the word line WL, the string selection line SSL, and the ground selection line GSL. In the memory cell array 20, a plurality of memory cells in each of the memory cell blocks BLK1, BLK2, . . . , and BLKn (n is a positive integer) may include flash memory cells. The memory cell array 20 may include a three-dimensional (3D) memory cell array. The 3D memory cell array may include a plurality of NAND strings. Each of the plurality of NAND strings may include a plurality of memory cells connected to vertically stacked word lines WL.

The peripheral circuit 30 may receive an address ADDR, a command CMD, and a control signal CTRL from the outside of the vertical non-volatile memory device 10 and may transmit data DATA to or receive the data DATA from a device located outside of the vertical non-volatile memory device 10.

The row decoder 32 may select at least one of the plurality of memory cell blocks BLK1, BLK2, . . . , and BLKn (n is a positive integer) in response to the address ADDR from the outside of the row decoder 32 and may select the word line WL, the string selection line SSL, and/or the ground selection line GSL of the selected memory cell block. The row decoder 32 may transmit a voltage for performing a memory operation to the word line WL of the selected memory cell block.

The page buffer 34 may be electrically connected to the memory cell array 20 via the bit line BL. The page buffer 34 may operate as a write driver during a program operation and apply a voltage to the bit line BL according to the data DATA to be stored in the memory cell array 20, and the page buffer 34 may operate as a sensing amplifier during a read operation and sense the data DATA stored in the memory cell array 20. The page buffer 34 may operate according to a control signal PCTL provided from the control logic 38.

The data I/O circuit 36 may be connected to the page buffer 34 via a plurality of data lines DLs. The data I/O circuit 36 may receive data DATA from a memory controller (not shown) during the program operation and may provide program data DATA to the page buffer 34 on the basis of a column address C_ADDR provided from the control logic 38. The data I/O circuit 36 may provide read data DATA stored in the page buffer 34 to the memory controller on the basis of the column address C_ADDR provided from the control logic 38 during the read operation.

The data I/O circuit 36 may transmit an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data I/O circuit 36. In response to the control signal CTRL, the control logic 38 may generate various internal control signals used in the vertical non-volatile memory device 10. For example, the control logic 38 may adjust a voltage level provided to the word line WL and the bit line BL, when performing memory operations, such as a program operation and an erase operation.

A common source line driver 39 may be electrically connected to the memory cell array 20 via a common source line CSL. The common source line driver 39 may apply a common source voltage (e.g., a power voltage) or a ground voltage to the common source line CSL on the basis of a control signal CTRL_BIAS of the control logic 38. In some embodiments, the common source line driver 39 may be located below the memory cell array 20 in plan view. The common source line driver 39 may at least partially overlap the memory cell array 20 in the vertical direction.

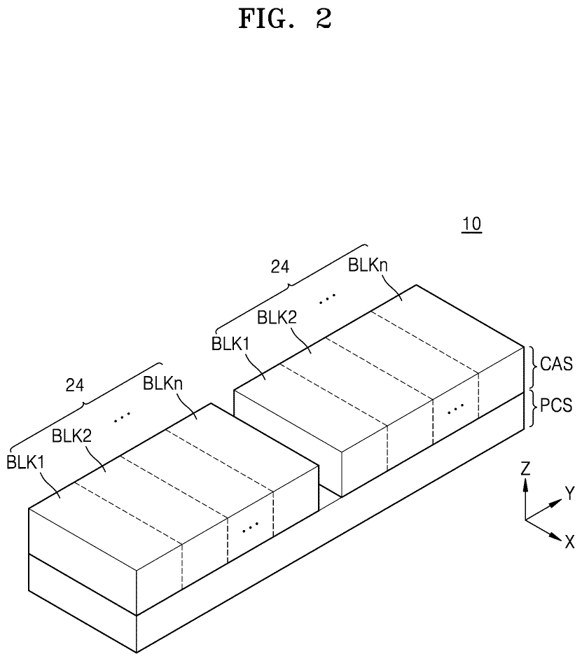

FIG. 2 is a schematic perspective view of a vertical non-volatile memory device 10 according to some embodiments.

Specifically, the vertical non-volatile memory device 10 may include a cell array structure CAS and a peripheral circuit structure PCS that overlap each other in a vertical direction (a Z direction). The X direction or −X direction may be referred to as a first horizontal direction. The Y direction or −Y direction may be referred to as a second horizontal direction. The Z direction may be referred to as a vertical direction.

In FIG. 2, the cell array structure CAS is stacked on the peripheral circuit structure PCS in the vertical direction (the Z direction). However, if necessary, the peripheral circuit structure PCS may be arranged on one side of the cell array structure CAS in the first horizontal direction (the X direction).

The cell array structure CAS may include the memory cell array 20 of FIG. 1. The peripheral circuit structure PCS may include the peripheral circuit 30 of FIG. 1. The cell array structure CAS of FIG. 2 may include a plurality of tiles 24. Each of the tiles 24 may include a plurality of memory cell blocks BLK1, BLK2, . . . , and BLKn (n is a positive integer). Each of the memory cell blocks BLK1, BLK2, . . . , and BLKn (n is a positive integer) may include a plurality of memory cells arranged three-dimensionally.

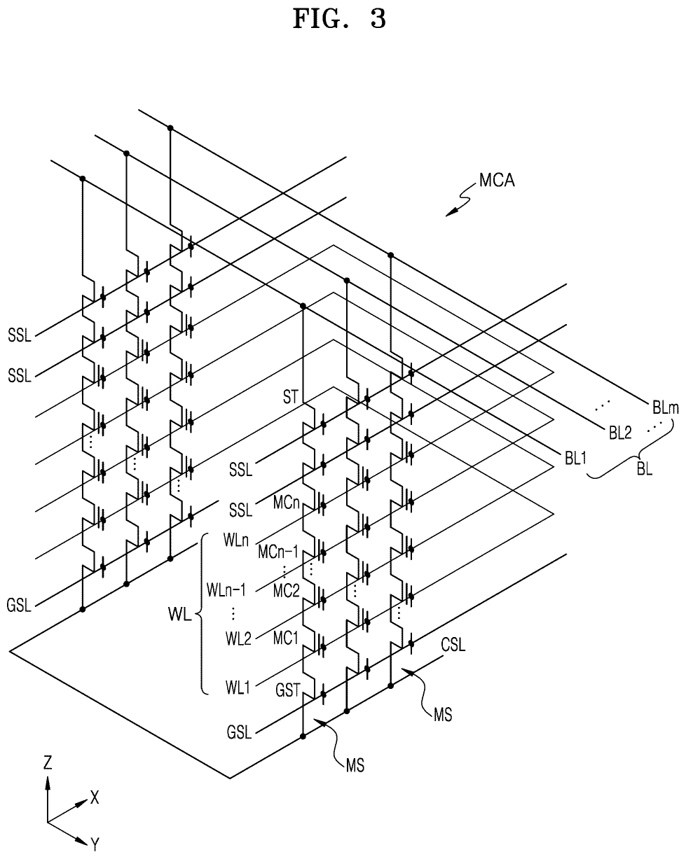

FIG. 3 is an equivalent circuit diagram of a memory cell array MCA of a vertical non-volatile memory device according to some embodiments.

Specifically, FIG. 3 may show an equivalent circuit diagram of the memory cell array MCA of the vertical non-volatile memory device 10 described above, for example, a vertical NAND flash memory device. The memory cell blocks BLK1, BLK2, . . . , and BLKn (n is a positive integer) of FIG. 2 may each include the memory cell array MCA having a circuit configuration illustrated in FIG. 3.

The memory cell array MCA may include a plurality of memory cell strings MS. The memory cell array MCA may include a plurality of bit lines BL (BL1, BL2, . . . , and BLm, where m is a positive integer), a plurality of word lines WL (WL1, WL2, . . . , WLn−1, and WLn, where n is a positive integer), a plurality of string selection lines SSL, a plurality of ground selection lines GSL, and a plurality of common source lines CSL.

The plurality of memory cell strings MS may be formed between the bit lines BL and the common source lines CSL. Although FIG. 3 illustrates a case in which each of the memory cell strings MS includes two string selection lines SSL, the inventive concept is not limited thereto. For example, each of the memory cell strings MS may include one string selection line SSL.

Each of the memory cell strings MS may include a string selection transistor ST, a ground selection transistor GST, and a plurality of memory cell transistors MC1, MC2, . . . , MCn−1, and MCn (n is a positive integer). The memory cell transistors MC1, MC2, . . . , MCn−1, and MCn (n is a positive integer) may include memory cells.

The drain region of the string selection transistor ST may be electrically connected to the bit line BL, and the source region of the ground selection transistor GST may be electrically connected to the common source line CSL. The common source line CSL may have a region to which source regions of a plurality of ground selection transistors GST are connected in common.

The string selection transistor ST may be connected to the string selection line SSL, and the ground selection transistor GST may be electrically connected to the ground selection line GSL. The plurality of memory cell transistors MC1, MC2, . . . , MCn−1, and MCn (n is a positive integer) may be respectively connected to the plurality of word lines WL.

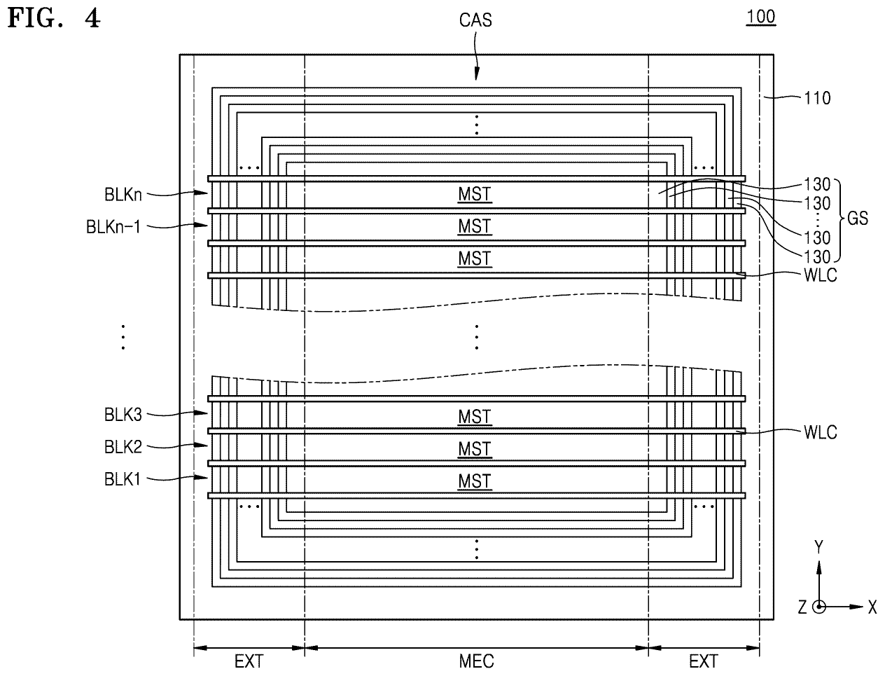

FIG. 4 is a schematic plan view of a vertical non-volatile memory device 100 according to some embodiments.

Specifically, the vertical non-volatile memory device 100 of FIG. 4 may be some embodiments in which the vertical non-volatile memory device 10 of FIGS. 1 to 3 is embodied. The descriptions given above with reference to FIGS. 1 to 3 are briefly given or omitted when illustrating the following diagrams.

A cell array structure CAS of the vertical non-volatile memory device 100 may include a substrate 110 and a plurality of memory cell blocks BLK1, BLK2, . . . , BLKn−1, and BLKn (n is a positive integer) arranged on the substrate 110.

The cell array structure CAS may include a memory cell region MEC and an extension region EXT adjacent to the memory cell region MEC in the first horizontal direction (the X direction). The extension region EXT may be located on one side of the memory cell region MEC. The extension region EXT may be referred to as a connection region.

Each of the memory cell blocks BLK1, BLK2, . . . , BLKn−1, and BLKn (n is a positive integer) may include a memory stack structure MST extending in the first horizontal direction (the X direction) across the memory cell region MEC and the extension region EXT.

The memory stack structure MST may include a plurality of first gate lines 130 that are stacked overlapping each other in the vertical direction (the Z direction) in the memory cell region MEC and the extension region EXT on the substrate 110. In each of the memory stack structures MST, the first gate lines 130 may form a gate stack GS. The first gate lines 130 may correspond to the word lines WL of FIGS. 1 and 3 described above.

The memory stack structures MST may each include a plurality of memory stacks that are at different vertical levels or heights in the vertical direction (the Z direction) and overlap each other in the vertical direction (the Z direction). The memory stacks may each include the first gate lines 130 that overlap each other in the vertical direction (the Z direction). In embodiments, the memory stacks may each include 48, 64, or 96 first gate lines 130 stacked so as to overlap one another in the vertical direction (the Z direction). However, the embodiments are not limited thereto.

In some embodiments, the area of the first gate lines 130 in the memory stack structures MST in the X-Y plane may gradually decrease as the distance from the substrate 110 increases. The central portion of each of the first gate lines 130 overlapping each other in the vertical direction (the Z direction) may constitute or include the memory cell region MEC, and the edge portion of each of the first gate lines 130 may constitute or include the extension region EXT.

A plurality of word line-cut structures WLC extending in the first horizontal direction (the X direction) in the memory cell region MEC and the extension region EXT may be arranged on the substrate 110. The word line-cut structures WLC may be spaced apart from each other in the second horizontal direction (the Y direction). The memory cell blocks BLK1, BLK2, . . . , BLKn−1, and BLKn (n is a positive integer) may be located one by one between the word line-cut structures WLC.

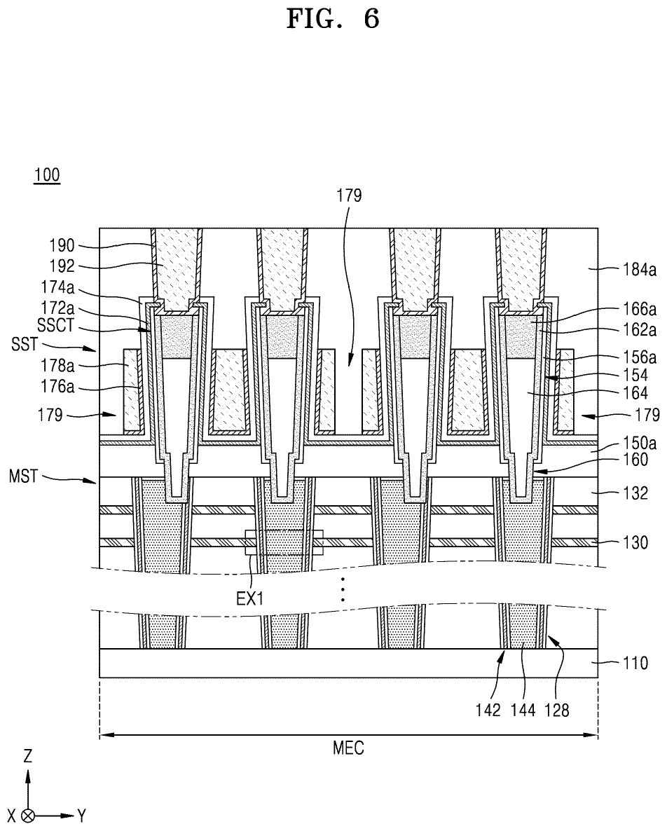

Each of the memory cell blocks BLK1, BLK2, . . . , BLKn−1, and BLKn (n is a positive integer) may include a string selection structure SST (see FIG. 6) on the memory stack structure MST that extends in the first horizontal direction (the X direction) across the memory cell region MEC and the extension region EXT. The string selection structure SST may include a string selection transistor ST and a string selection line SSL. The structure of the string selection structure SST is described in detail below.

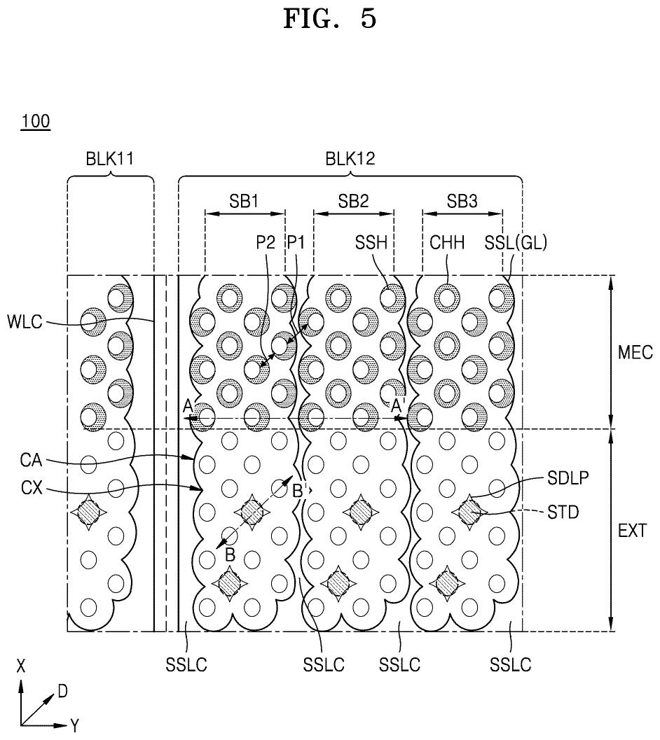

FIG. 5 is a schematic plan view illustrating a memory cell region MEC and an extension region EXT of a vertical non-volatile memory device 100 according to some embodiments.

Specifically, the vertical non-volatile memory device 100 of FIG. 5 may include memory cell blocks BLK11 and BLK12. The memory cell blocks BLK11 and BLK12 may constitute or include any one of the memory cell blocks BLK1 to BLKn (n is a positive integer) illustrated in FIG. 2.

The vertical non-volatile memory device 100 may include a memory cell region MEC and an extension region EXT. As described above in FIG. 4, the vertical non-volatile memory device 100 may have a plurality of word line-cut structures WLC that extend lengthwise in the first horizontal direction (the X direction) in the memory cell region MEC and the extension region EXT.

In the memory cell region MEC, a plurality of channel holes CHH may be spaced apart from each other in the first horizontal direction (the X direction) and the second horizontal direction (the Y direction). The channel holes CHH may be aligned with each other in the first horizontal direction (the X direction) and the second horizontal direction (the Y direction). The channel holes CHH may be aligned with each other in a diagonal direction (a D direction).

A plurality of string selection line holes SSH may be arranged in the memory cell region MEC and the extension region EXT. The string selection line holes SSH may be aligned with each other in the first horizontal direction (the X direction) and the second horizontal direction (the Y direction). The string selection line holes SSH may be arranged in the diagonal direction (the D direction). The diagonal direction (the D direction) may also be broadly referred to as the second horizontal direction.

In the memory cell region MEC, the channel holes CHH and the string selection line holes SSH may partially overlap each other in a plan view. The memory cell region MEC and the extension region EXT may have a plurality of string selection lines SSL that extend in the first horizontal direction (the X direction) and spaced apart from each other in the second horizontal direction (the Y direction).

The string selection lines SSL may include second gate lines GL for operating the string selection transistor ST of FIG. 3. The string selection lines SSL may be separated from each other in the second horizontal direction (the Y direction) by a string selection line-cut structure SSLC. The string selection line-cut structure SSLC may include be a string line-cut pattern.

The string selection lines SSL may include sub-blocks SB1, SB2, and SB3. The sub-blocks SB1, SB2, and SB3 may be separated from each other by the string selection line-cut structure SSLC. The word line-cut structures WLC may be separated from the string selection lines SSL by the string selection line-cut structure SSLC.

Each of the string selection lines SSL (the second gate lines GL) may cover or overlap the plurality of string selection line holes SSH. The string selection lines SSL (the second gate lines GL) may have a curved shape having a concave portion CX and a convex portion CA in the first horizontal direction. The concave portion CX may include a cusp as shown in FIG. 5. The concave portion CX may have a recessed surface, unlike in FIG. 5.

The string selection lines SSL (the second gate lines GL) may have a wave pattern extending in the first horizontal direction. The string selection lines SSL (the second gate lines GL) may not be a straight line pattern extending in the first horizontal direction.

A distance P2 between the string selection line holes SSH located inside each of the string selection lines SSL (the second gate lines GL) may be less than a distance P1 between the string selection line holes SSH located between the string selection lines SSL (the second gate lines GL). Accordingly, as described below, the string selection lines SSL (the second gate lines GL) may have a curved shape in the first horizontal direction (the X direction).

In the extension region EXT, a contact insulating pattern SDLP may be located between the string selection line holes SSH. In FIG. 5, the contact insulating pattern SDLP is located between the string selection line holes SSH in the diagonal direction (the D direction). However, the contact insulating pattern SDLP may be located between the string selection line holes SSH in the first horizontal direction or the second horizontal direction.

The contact insulating pattern SDLP may include a stud insulating pattern. A conductive plug STD may be located within the contact insulating pattern SDLP. The conductive plug STD may include a string selection line-conductive plug.

FIGS. 6 to 9 are cross-sectional views illustrating a memory stack structure MST and a string selection structure SST in a memory cell region MEC of a vertical non-volatile memory device according to some embodiments.

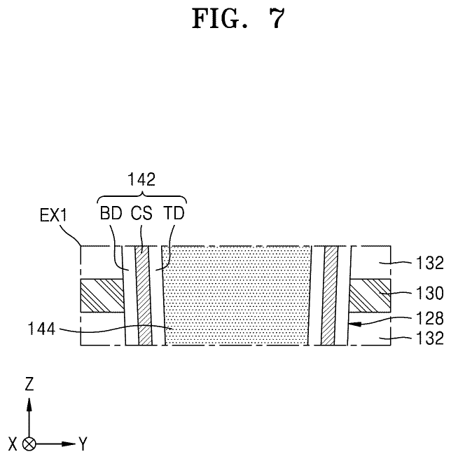

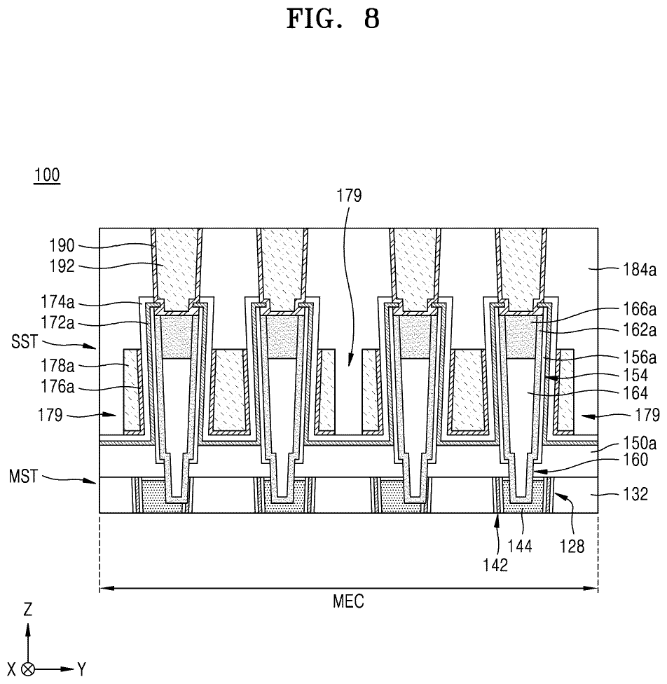

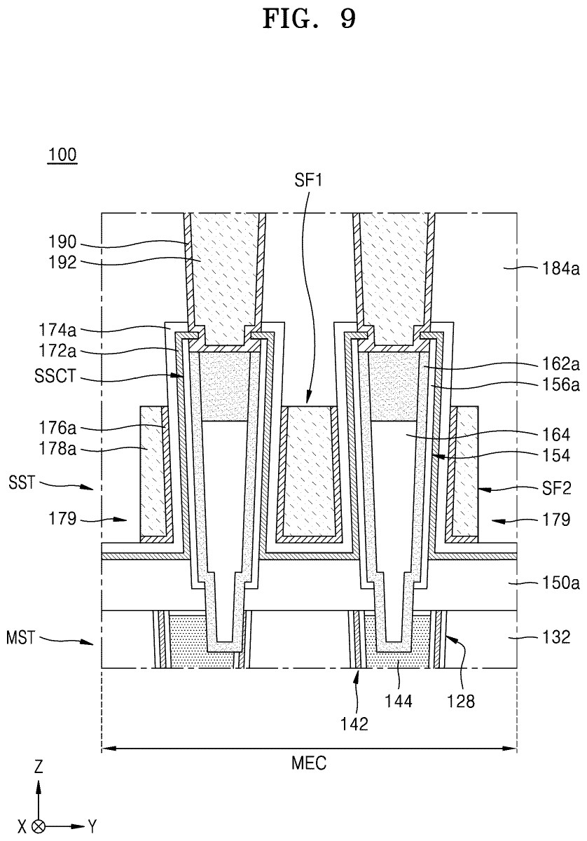

Specifically, FIG. 6 may be a cross-sectional view of the vertical non-volatile memory device taken along line A-A′ of FIG. 5, and FIG. 7 may be an enlarged cross-sectional view of region “EX1” of FIG. 6. FIG. 8 is a cross-sectional view illustrating the memory stack structure MST and the string selection structure SST in the memory cell region MEC of FIG. 6, and FIG. 9 is an enlarged cross-sectional view illustrating a portion of FIG. 8.

The memory cell region MEC of the vertical non-volatile memory device 100 may include a memory stack structure MST and a string selection structure SST. The string selection structure SST may be disposed above the memory stack structure MST.

The memory stack structure MST may include a plurality of first channel regions 144 arranged in channel holes 128 and extending in the vertical direction above a substrate 110, a plurality of first gate dielectric layers 142 surrounding or extending around the first channel regions 144 in plan view, and a plurality of first gate lines 130 surrounding or extending around the first gate dielectric layers 142 in plan view and stacked to be spaced apart from each other in the vertical direction.

The channel holes 128 may correspond to the channel holes CHH of FIG. 5. The channel holes 128 may be spaced apart from each other in the first horizontal direction (the X direction) and the second horizontal direction (the Y direction) as described above. The first channel regions 144 may be arranged inside the channel holes 128 with the first gate dielectric layers 142 therebetween. The first channel regions 144 may include doped polysilicon or undoped polysilicon.

The first gate dielectric layers 142 may each include a first tunnel dielectric layer TD, a first charge storage layer CS, and a first blocking dielectric layer BD, which are sequentially arranged from the first channel region 144 toward the first gate line 130, as shown in FIG. 7.

The first tunnel dielectric layer TD may include silicon oxide, hafnium oxide, aluminum oxide, zirconium oxide, tantalum oxide, etc. The first charge storage layer CS may have a region capable of storing electrons that have passed through the first tunnel dielectric layer TD from the first channel regions 144 and may include silicon nitride, boron nitride, silicon boron nitride, or polysilicon doped with impurities. The first blocking dielectric layer BD may include silicon oxide, silicon nitride, or metal oxide with a greater dielectric constant than the silicon oxide. The metal oxide may include hafnium oxide, aluminum oxide, zirconium oxide, tantalum oxide, or a combination thereof.

The first gate lines 130 may be insulated from each other by insulating layers 132. The insulating layers 132 may include a silicon oxide layer. For convenience, the common source line CSL, the ground selection transistor GST, and the ground selection transistor GST on the substrate 110 are not shown in FIG. 6. The first gate lines 130 may correspond to the memory cell-word line WL of FIGS. 1 and 3 described above.

The string selection structure SST may include a plurality of second channel regions 162a arranged inside string selection line holes 154 and 160 extending in the vertical direction (the Z direction), a plurality of second gate dielectric layers 156a, 172a, and 174a arranged on the upper surface and both side surfaces of the second channel regions 162a, and a plurality of second gate lines 176a and 178a surrounding or extending around the second gate dielectric layers 156a, 172a, and 174a in plan view and spaced apart from each other between sub-blocks (SB1, SB2, and SB3 in FIG. 5) in the second horizontal direction (the Y direction).

The string selection line holes 154 and 160 may correspond to the string selection line holes SSH of FIG. 5. The string selection line holes 154 and 160 may be spaced apart from each other in the first horizontal direction (the X direction) and the second horizontal direction (the Y direction) as illustrated in FIG. 5.

The string selection line holes 154 and 160 may include a lower hole 160 located in a middle insulating layer 150a and an upper hole 154 communicating with or adjacent to the lower hole 160 in the vertical direction (hereinafter, the string selection line holes 154 and 160 may also be referred to as the upper hole 154 and the lower hole 160, respectively). The string selection line holes 154 and 160 may overlap channel holes 128 in the vertical direction. The second channel regions 162a are insulated by the middle insulating layer 150a on the memory stack structure MST.

The second channel regions 162a may include doped polysilicon or undoped polysilicon. The second channel regions 162a may include cylinders. The second channel regions 162a may be connected to the first channel regions 144 in the vertical direction inside the string selection line holes 154 and 160.

The second gate dielectric layers 156a, 172a, and 174a may include a second tunnel dielectric layer 156a, a second charge storage layer 172a, and a second blocking dielectric layer 174a, which are sequentially arranged from the second channel regions 162a toward second gate lines 176a and 178a (hereinafter, the second gate dielectric layers 156a, 172a, and 174a may also be referred to as the second tunnel dielectric layer 156a, the second charge storage layer 172a, and the second blocking dielectric layer 174a, respectively). The second gate dielectric layers 156a, 172a, and 174a including the second tunnel dielectric layer 156a, the second charge storage layer 172a, and the second blocking dielectric layer 174a may be arranged between the second channel regions 162a and the second gate lines 176a and 178a in the second horizontal direction.

The second gate dielectric layers 156a, 172a, and 174a may be arranged on portions of the upper surfaces and both side surfaces of the second channel regions 162a. The second tunnel dielectric layer 156a, the second charge storage layer 172a, and the second blocking dielectric layer 174a may include the same materials as the first tunnel dielectric layer TD, the first charge storage layer CS, and the first blocking dielectric layer BD, respectively, illustrated in FIG. 7.

The string selection structure SST may include string selection cylinder structures SSCT that include second channel regions 162a having cylinders, buried insulating layers 164 partially filling the inner spaces of the cylinders of the second channel regions 162a, and drain conductive layers 166a formed on the buried insulating layers 164 inside the cylinders.

The upper surfaces of the second gate lines 176a and 178a may be lower than the upper surfaces of the drain conductive layers 166a in the vertical direction. The second gate lines 176a and 178a may be separated from each other in the second horizontal direction (the Y direction) by an insulating structure 179. The insulating structure 179 may include the string selection line-cut structure SSLC (the string line-cut pattern) of FIG. 5.

The second gate lines 176a and 178a may cover or overlap the plurality of second channel regions 162a. The second gate lines 176a and 178a may be separated from each other by string selection line-cut structures extending in the first horizontal direction and spaced apart from each other in the second horizontal direction.

The second gate lines 176a and 178a may include a metal layer. The second gate lines 176a and 178a may include a barrier metal layer 176a and a gate metal layer 178a (hereinafter, the second gate lines 176a and 178a may also be referred to as the barrier metal layer 176a and the gate metal layer 178a, respectively). The barrier metal layer 176a may include titanium (Ti), titanium nitride (TiN), tantalum (Ta), tantalum nitride (TaN), or the like. The gate metal layer 178a may include metals, such as tungsten (W), nickel (Ni), cobalt (Co), copper (Cu), aluminum (Al), or molybdenum (Mo). The second gate lines 176a and 178a may correspond to the string selection lines described above. The second gate lines 176a and 178a may include string selection line-word lines.

One sidewall of the second gate lines 176a and 178a exposed by the insulating structure 179 may have a curved shape having concave portions and convex portions in the first horizontal direction (the X direction) as illustrated in FIG. 5. As illustrated in FIG. 9, no barrier metal layer may be disposed on upper surfaces SF1 and side surfaces SF2 of the second gate lines 176a and 178a exposed by the insulating structure 179. No barrier metal layer is disposed on the upper surfaces SF1 and side surfaces SF2 of the second gate lines 176a and 178a located on the outermost sides in the second horizontal direction.

The string selection structure SST includes bit line-conductive plugs 190 and 192 connected to the drain conductive layers 166a. The bit line-conductive plugs 190 and 192 may include a barrier metal layer 190 and a plug metal layer 192 (hereinafter, the bit line-conductive plugs 190 and 192 may also be referred to as the barrier metal layer 190 and the plug metal layer 192, respectively). The bit line-conductive plugs 190 and 192 and the string selection cylinder structures SSCT may be insulated by an interlayer insulating layer 184a.

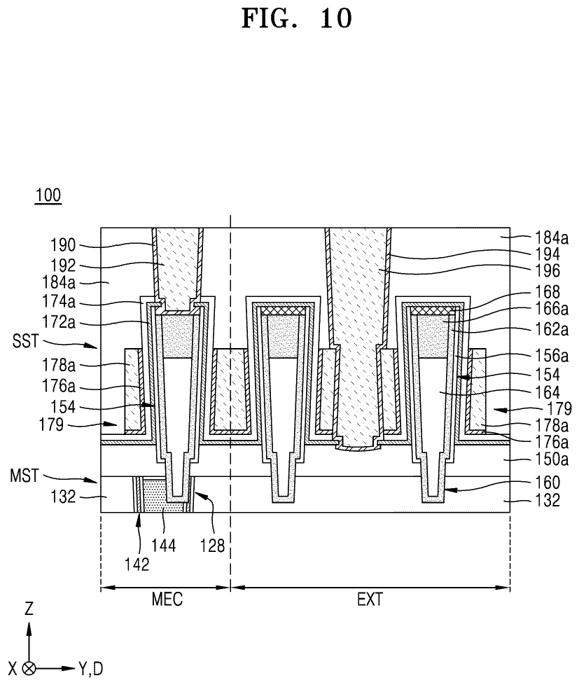

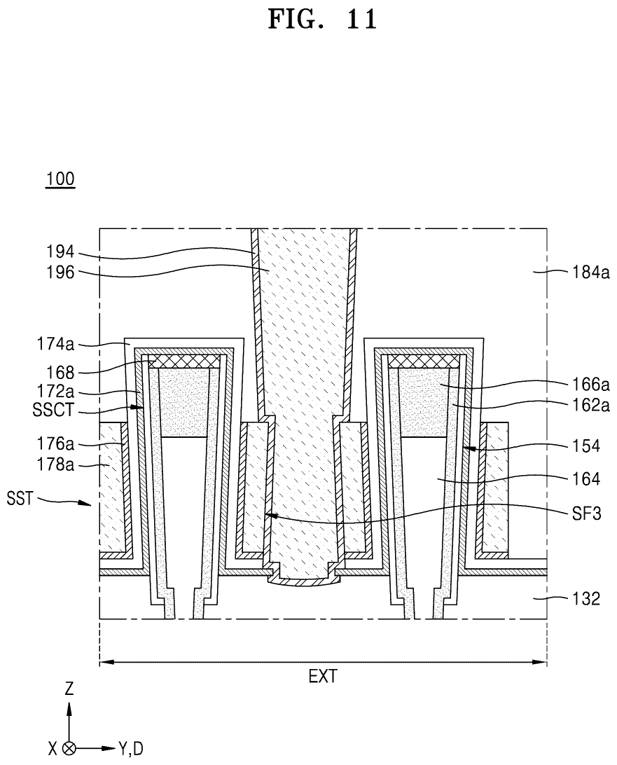

FIGS. 10 and 11 are cross-sectional views illustrating a memory stack structure MST and a string selection structure SST in an extension region EXT of a vertical non-volatile memory device according to some embodiments.

Specifically, the extension region EXT of FIGS. 10 and 11 may be based on cross-sectional views of the vertical non-volatile memory device taken along line B-B′ of FIG. 5. FIG. 11 may be an enlarged view of part of FIG. 10. In FIGS. 10 and 11, the string selection structure SST of the extension region EXT is mainly described. The descriptions given above with reference to FIGS. 6 to 9 are briefly given or omitted when describing FIGS. 10 and 11.

As described above, the string selection structure SST may include a plurality of second channel regions 162a arranged inside string selection line holes 154 and 160 extending in the vertical direction (the Z direction), a plurality of second gate dielectric layers 156a, 172a, and 174a arranged on the upper surface and both side surfaces of the second channel regions 162a, and a plurality of second gate lines 176a and 178a surrounding or extending around the second gate dielectric layers 156a, 172a, and 174a in plan view and spaced apart from each other between sub-blocks (SB1, SB2, and SB3 in FIG. 5) in the second horizontal direction (the Y direction). The second gate dielectric layers 156a, 172a, and 174a of the extension region EXT may extend in the second horizontal direction (the Y direction) or the diagonal direction (the D direction).

In addition, the string selection structure SST may include string selection cylinder structures SSCT having, as described above, second channel regions 162a having cylinders, buried insulating layers 164 partially filling the inner spaces of the cylinders of the second channel regions 162a, and drain conductive layers 166a formed on the buried insulating layers 164 inside the cylinders.

The second gate dielectric layers 156a, 172a, and 174a may be arranged on the upper surfaces and side surfaces of the second channel regions 162a. The second gate dielectric layers 156a, 172a, and 174a of the string selection structure SST extend in the second horizontal direction on the upper surface and both side surfaces of the second channel regions 162a in the extension region EXT.

The string selection structure SST further includes capping insulating layers 168 formed on the second channel regions 162a and the drain conductive layers 166a of the string selection cylinder structures SSCT. The second gate dielectric layers 156a, 172a, and 174a of the string selection structure SST are arranged on the entire upper surface and the entire side surfaces of the second channel regions 162a in the extension region EXT.

The string selection structure SST may include string selection line-conductive plugs 194 and 196 in contact with one side of the second gate lines 176a and 178a in the extension region EXT. When the string selection line-conductive plugs 194 and 196 are in contact with one side of the second gate lines 176a and 178a, the device reliability may be further improved.

The string selection line-conductive plugs 194 and 196 may include a barrier metal layer 194 and a plug metal layer 196 (hereinafter, the string selection line-conductive plugs 194 and 196 may also be referred to as the barrier metal layer 194 and the plug metal layer 196, respectively). The barrier metal layer 194 may include titanium (Ti), titanium nitride (TiN), tantalum (Ta), tantalum nitride (TaN), or the like. The plug metal layer 196 may include metals, such as tungsten (W), nickel (Ni), cobalt (Co), copper (Cu), aluminum (Al), or molybdenum (Mo). The string selection line-conductive plugs 194 and 196 and the string selection cylinder structures SSCT may be insulated by an interlayer insulating layer 184a.

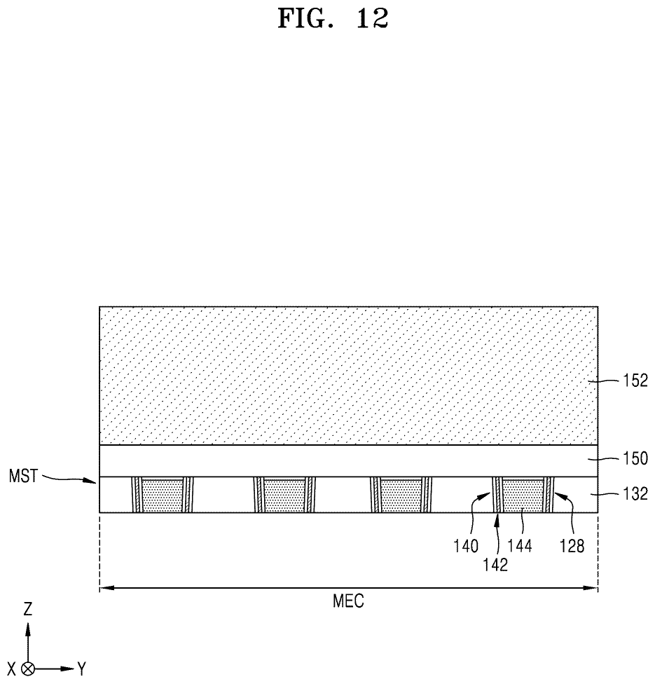

FIGS. 12 to 26 are cross-sectional views illustrating a method of manufacturing the memory stack structure and the string selection structure in the vertical non-volatile memory device of FIGS. 6 to 11.

Specifically, in FIGS. 12 to 26, the same reference numerals as in FIGS. 6 to 11 indicate the same members. The descriptions given above with reference to FIGS. 6 to 11 are briefly given or omitted when describing FIGS. 12 to 26.

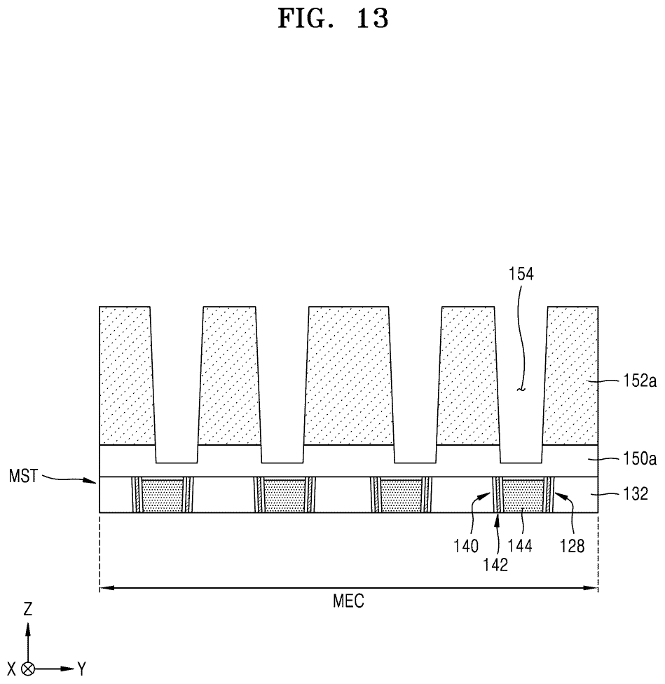

Referring to FIGS. 12 and 13, a memory stack structure MST is formed on a substrate 110 (FIG. 6) as illustrated in FIG. 12. The memory stack structure MST may include a plurality of channel structures 140, a plurality of first gate lines 130 (FIG. 6), and first insulating layers 132 (FIG. 6).

The channel structures 140 may include a first gate dielectric layer 142 formed within channel holes 128 formed in a vertical direction (a Z direction) inside the first insulating layer 132 and a first channel region 144 formed on the inside of the first gate dielectric layer 142 within the channel holes 128.

The first gate dielectric layer 142 may include a first tunnel dielectric layer TD, a first charge storage layer CS, and a first blocking dielectric layer BD, as illustrated in FIG. 7. The first gate lines 130 may be spaced apart from each other in the vertical direction while surrounding or extending around the channel holes 128 inside the first insulating layer 132.

A second insulating material layer 150 and a third insulating material layer 152 are sequentially formed on the memory stack structure MST. The second insulating material layer 150 and the third insulating material layer 152 are sequentially formed on the channel structure 140 and the first insulating layer 132.

The third insulating material layer 152 may be thicker than the second insulating material layer 150. The third insulating material layer 152 may include a different material from the second insulating material layer 150. The second insulating material layer 150 may include a silicon oxide layer. The third insulating material layer 152 may include a silicon nitride layer.

As shown in FIG. 13, the third insulating material layer 152 (FIG. 12) and the second insulating material layer 150 (FIG. 12) are sequentially patterned to form a third insulating layer 152a and a second insulating layer 150a having first holes 154 above the channel structure 140. As the first holes 154 are formed, the third insulating material layer 152 and the second insulating material layer 150 are changed into the third insulating layer 152a and the second insulating layer 150a, respectively.

As described above with reference to FIG. 12, the third insulating material layer 152 and the second insulating material layer 150 may include different materials. Depending on the etch selectivity of the third insulating material layer 152 and the second insulating material layer 150, the bottom of the first holes 154 may be formed in the middle of the second insulating layer 150a. The first holes 154 may become string selection line holes 154 through a post-process.

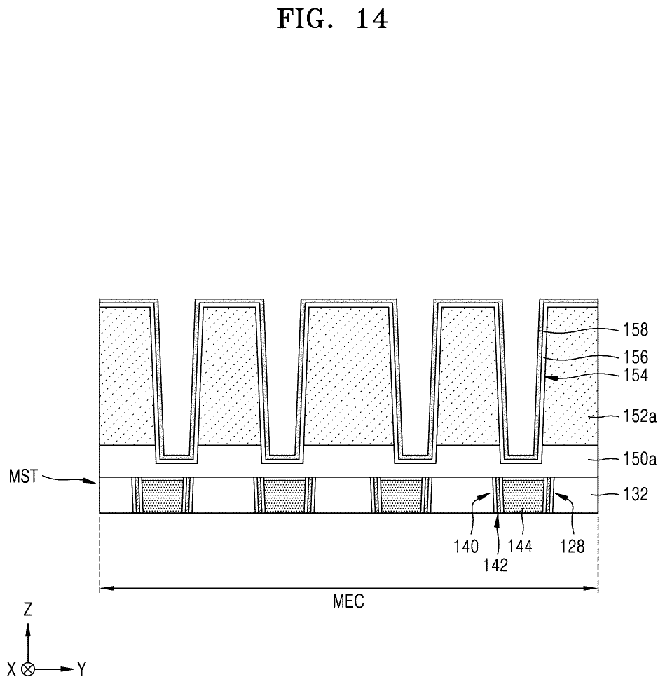

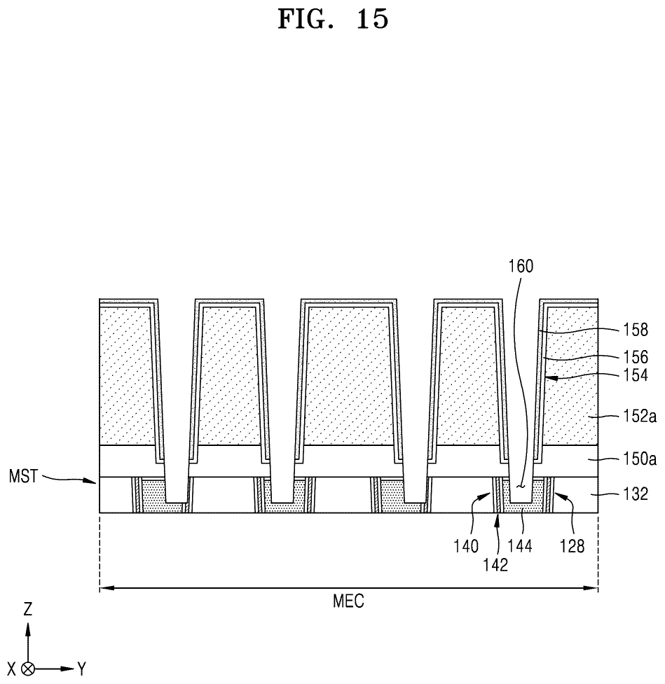

Referring to FIGS. 14 and 15, a second tunnel dielectric material layer 156 is formed on the inside and bottom of the first hole 154 and above the second insulating layer 150a and the third insulating layer 152a, as shown in FIG. 14. A spacer material layer 158 is formed on the second tunnel dielectric material layer 156.

The spacer material layer 158 may be formed on the inner wall and bottom of the first hole 154 and above the third insulating layer 152a on the side wall of the first hole 154. The second tunnel dielectric material layer 156 may include an oxide layer. The spacer material layer 158 may include a polysilicon layer.

As shown in FIG. 15, the spacer material layer 158 located at the bottom of the first hole 154, the second insulating layer 150a at the bottom of the first hole 154, the second tunnel dielectric material layer 156 at the bottom of the first hole 154, and the upper portion of the first channel region 144 below the first hole 154 are etched to form a second hole 160.

The second hole 160 may communicate with or be adjacent to the first hole 154. The bottom of the second hole 160 may correspond to the inside of the upper portion of the first channel region 144. The first hole 154 and the second hole 160 may overlap a channel hole 128. The first hole 154 and the second hole 160 may correspond to a string selection line hole.

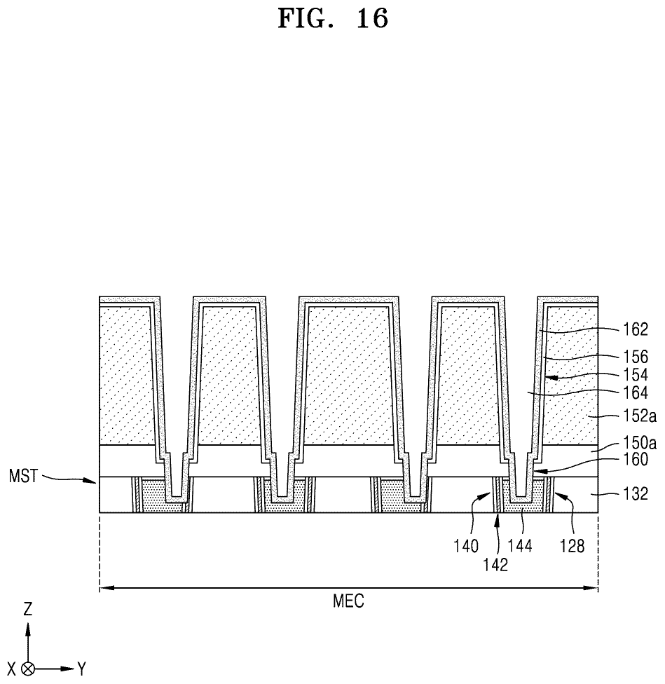

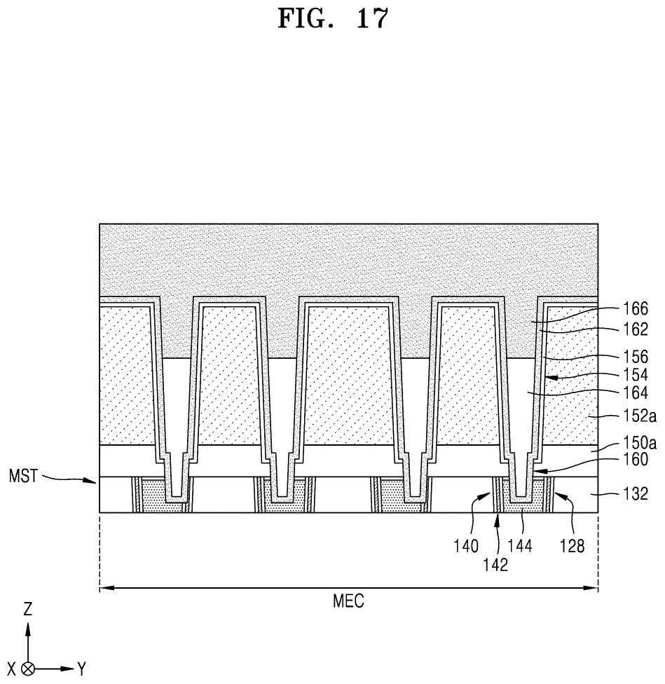

Referring to FIGS. 16 and 17, a second channel material layer 162 is formed, as shown in FIG. 16, on the inside and bottom of the first hole 154 and the second hole 160, above the spacer material layer 158 inside the first hole 154 and the second hole 160, and above the third insulating layer 152a. The second channel material layer 162 may include a polysilicon layer. In FIG. 16, the spacer material layer 158 and the second channel material layer 162 may include the same material.

As illustrated in FIG. 17, a buried insulating layer 164 is formed on the second channel material layer 162 of the first hole 154 and the second hole 160 so as to partially fill the first hole 154 and the second hole 160. After a buried insulating material layer that completely fills the first hole 154 and the second hole 160 is formed on the second channel material layer 162, the buried insulating layer 164 may be formed by etching the buried insulating material layer (i.e., an etch-back process). The buried insulating layer 164 includes a silicon oxide layer.

A drain conductive material layer 166 that sufficiently fills the first hole 154 is formed on the buried insulating layer 164 and the second channel material layer 162. The drain conductive material layer 166 includes a polysilicon layer doped with impurities.

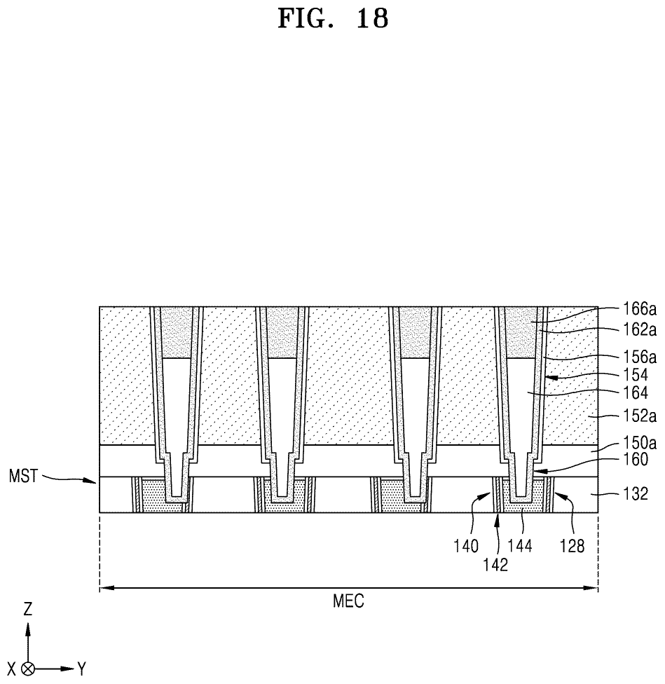

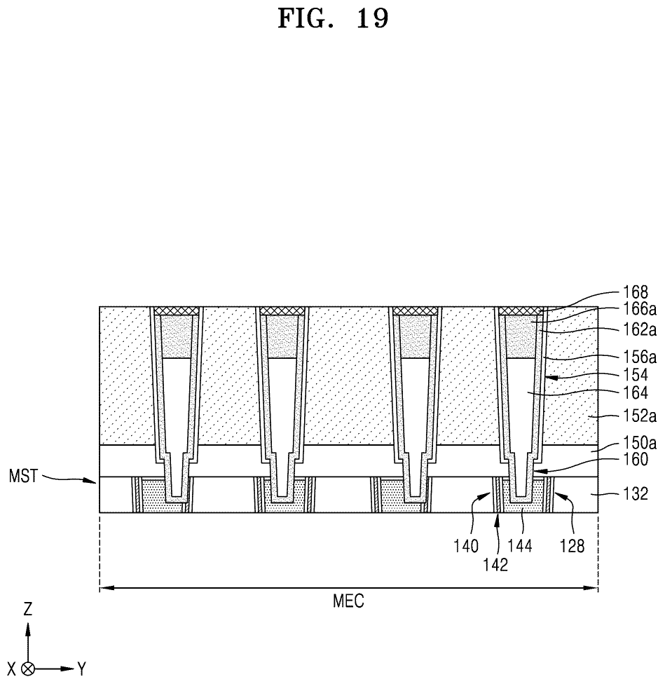

Referring to FIGS. 18 and 19, the drain conductive material layer 166, the second channel material layer 162, and the second tunnel dielectric material layer 156 are etched as shown in FIG. 18 (i.e., the etch-back process) using the upper surface of the third insulating layer 152a as an etch stop point.

Accordingly, a drain conductive layer 166a is formed on the buried insulating layer 164 of the first hole 154. In addition, a second channel region 162a having a cylinder structure may be formed on the inner walls of the first hole 154 and the second hole 160. A second tunnel dielectric layer 156a may be formed on the outer wall of the second channel region 162a having the cylinder structure. The drain conductive layer 166a may correspond to a drain region of a string selection transistor.

As shown in FIG. 19, the upper surfaces of the drain conductive layer 166a and the second channel region 162a are oxidized. A capping insulating layer 168 is formed on the sidewall of the second tunnel dielectric layer 156a of the first hole 154 and on the upper surfaces of the drain conductive layer 166a and the second channel region 162a. The capping insulating layer 168 includes a silicon oxide layer.

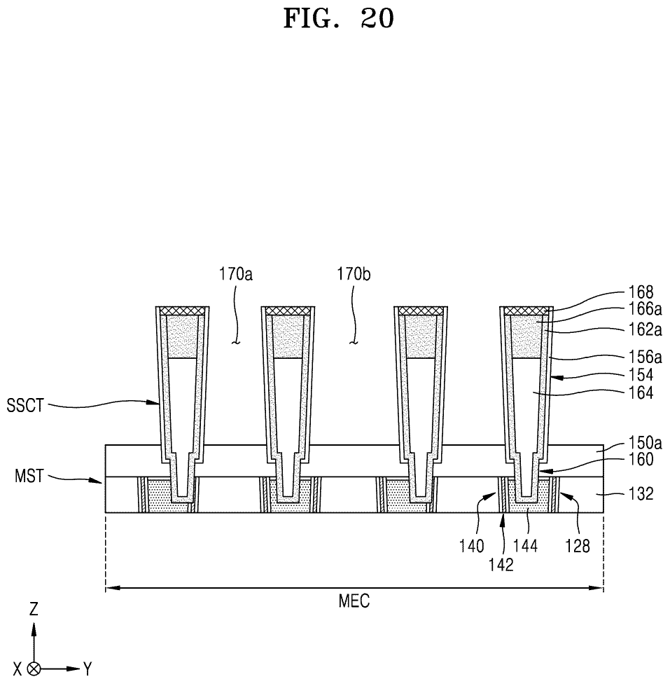

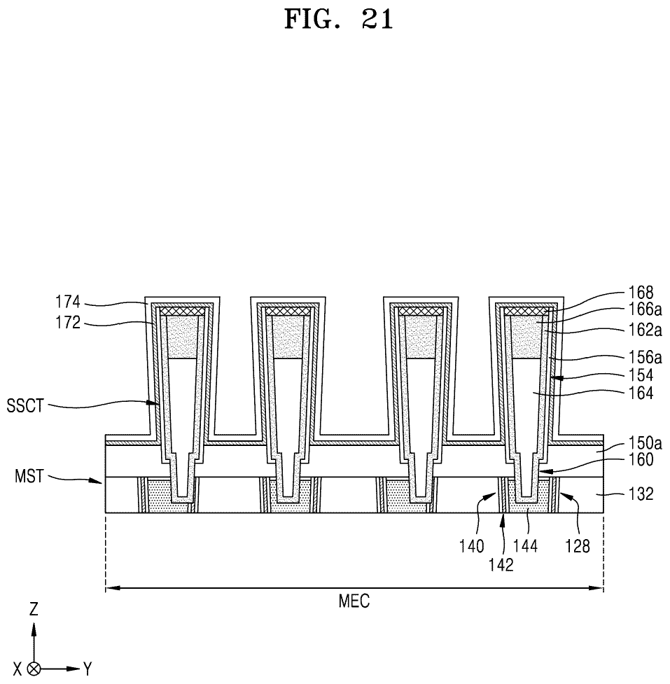

Referring to FIG. 20 and FIG. 21, the third insulating layer 152a formed on both sidewalls of the first hole 154 is etched and removed as shown in FIG. 20. Consequently, third holes 170a and 170b may be formed that exposes the outer wall of the first hole 154, the sidewall of the second tunnel dielectric layer 156a, and the upper surface of the second insulating layer 150a. The third holes 170a and 170b may include a narrow portion 170a and a wide portion 170b in a second horizontal direction (a Y direction) (hereinafter, the third holes 170a and 170b may also be referred to as the narrow portion 170a and the wide portion 170b, respectively).

In addition, the second channel region 162a of the cylinder structure, the drain conductive layer 166a, the buried insulating layer 164, and the capping insulating layer 168 may form string selection cylinder structures SSCT. The second tunnel dielectric layer 156a may be formed on one sidewall of the second channel region 162a having a cylinder structure protruding from the upper surface of the second insulating layer 150a. The narrow third hole 170a and the wide third hole 170b may be formed between the string selection cylinder structures SSCT in the second horizontal direction.

As shown in FIG. 21, a second charge storage material layer 172 and a second blocking dielectric material layer 174 are formed on the outer wall of the first hole 154, the sidewall of the second tunnel dielectric layer 156a, the upper surface of the second insulating layer 150a, and the upper surface of the capping insulating layer 168.

The second charge storage material layer 172 and the second blocking dielectric material layer 174 are formed on the second tunnel dielectric layer 156a formed on one sidewall of the second channel region 162a of the cylinder structure, on the upper surface of the second insulating layer 150a, and on the upper surface of the capping insulating layer 168.

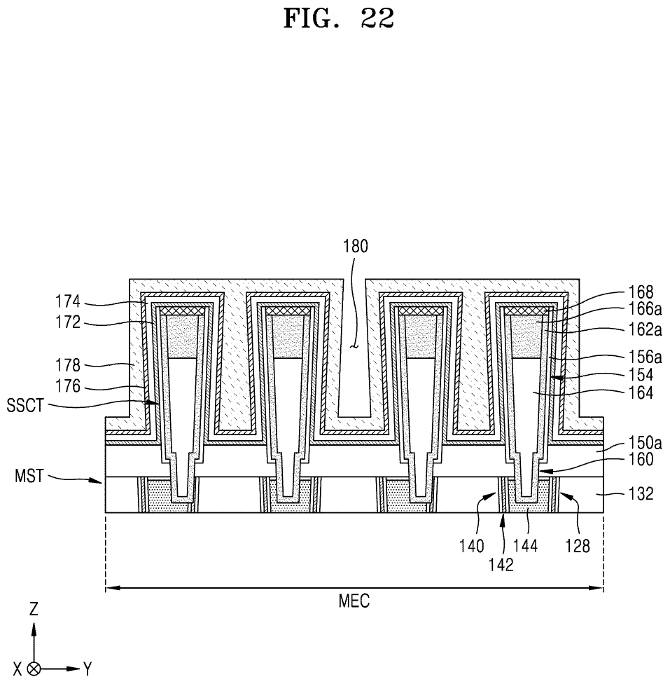

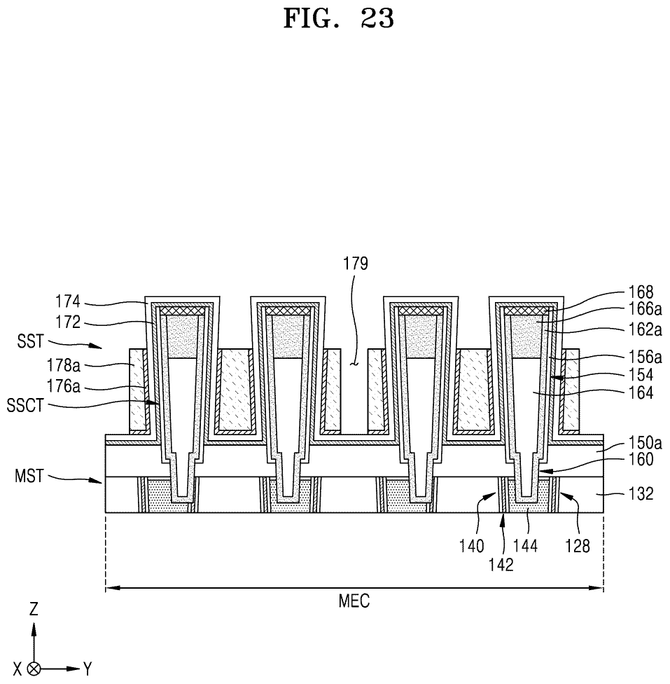

Referring to FIGS. 22 and 23, a barrier metal material layer 176 is formed on the second blocking dielectric material layer 174 as shown in FIG. 22. A gate metal material layer 178 is formed on the barrier metal material layer 176.

The barrier metal material layer 176 and the gate metal material layer 178 may partially or completely fill the narrow third hole 170a (FIG. 20) between the string selection cylinder structures SSCT. The barrier metal material layer 176 and the gate metal material layer 178 may not fill the wide third hole 170b (FIG. 20) between the string selection cylinder structures SSCT, and thus, a fourth hole 180 may be created.

As shown in FIG. 23, the barrier metal material layer 176 and the gate metal material layer 178 are etched back using the second blocking dielectric material layer 174 as an etch stop point, thereby forming second gate lines 176a and 178a. The barrier metal material layer 176 and the gate metal material layer 178 filling the narrow third hole 170a (FIG. 20) between the string selection cylinder structures SSCT are etched back to form the second gate lines 176a and 178a.

The second gate lines 176a and 178a may correspond to the string selection lines SSL described above. The string selection lines 176a, 178a, and SSL may include a metal layer instead of a polysilicon layer to lower the resistance and reduce the heat generated in a device.

The barrier metal material layer 176 and the gate metal material layer 178 that do not fill the wide third hole 170b (FIG. 20) between the string selection cylinder structures SSCT may be etched back and removed. A removed portion 179 within the fourth hole 180 (FIG. 22) may correspond to a string selection line-cut structure SSLC (or referred to as a string selection line-cut pattern 179).

The string selection line-cut structure (or the string selection line-cut pattern 179) is formed through etch-back rather than through a photolithography process, the manufacturing process may be simplified. Since the string selection line-cut structure (or the string selection line-cut pattern 179) is not formed through the photolithography process, the degree of freedom in design of the string selection line holes 154 and 160 may increase.

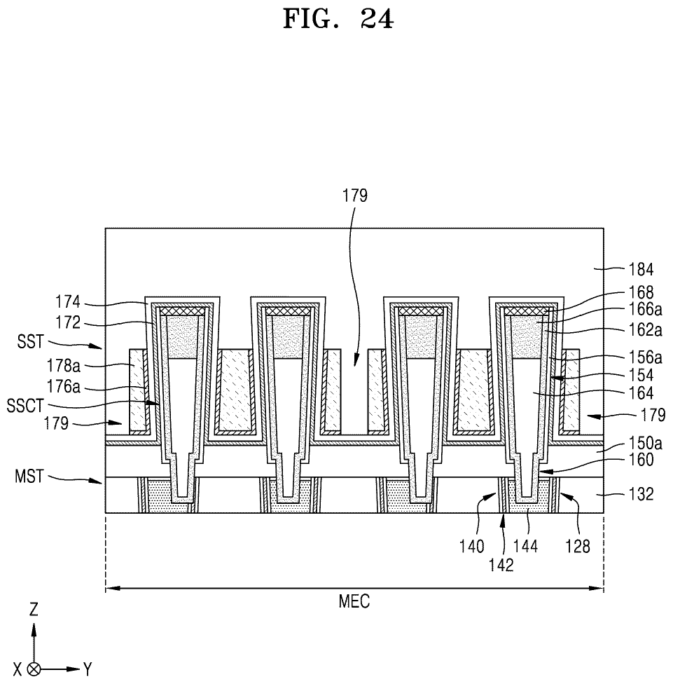

Referring to FIGS. 24 to 26, a fourth insulating material layer 184 is formed, as shown in FIG. 24, which covers or overlaps the string selection cylinder structures SSCT, the second gate lines 176a and 178a, the second tunnel dielectric layer 156a, the second charge storage material layer 172, and the second blocking dielectric material layer 174.

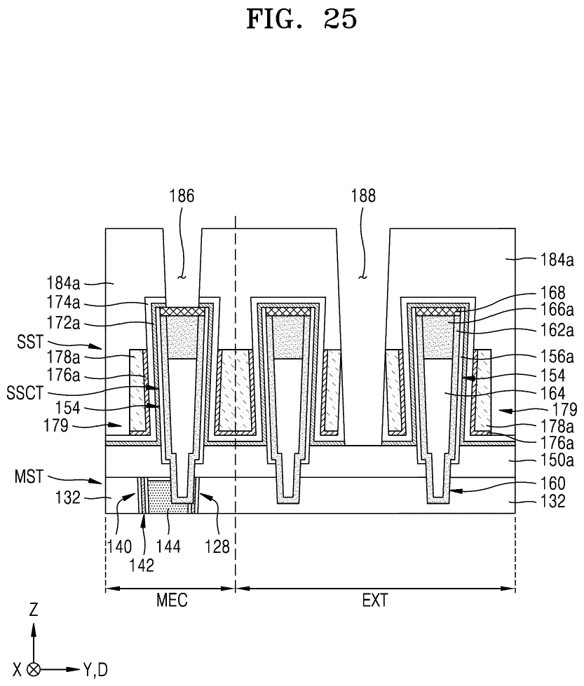

As illustrated in FIG. 25, the fourth insulating material layer 184 of the memory cell region MEC and the second charge storage material layer 172 and the second blocking dielectric material layer 174 on the capping insulating layer 168 of the memory cell region MEC are etched. Accordingly, a first contact hole 186 is formed that exposes the capping insulating layer 168 of the memory cell region MEC.

The fourth insulating material layer 184 of the extension region EXT is etched to form a second contact hole 188 that partially exposes the side surfaces of the second gate lines 176a and 178a of the extension region EXT. As the first contact hole 186 and the second contact hole 188 are formed, the fourth insulating material layer 184 may become a fourth insulating layer 184a.

As the first contact hole 186 and the second contact hole 188 are formed, the second charge storage material layer 172 and the second blocking dielectric material layer 174 may become a second charge storage layer 172a and a second blocking dielectric layer 174a, respectively.

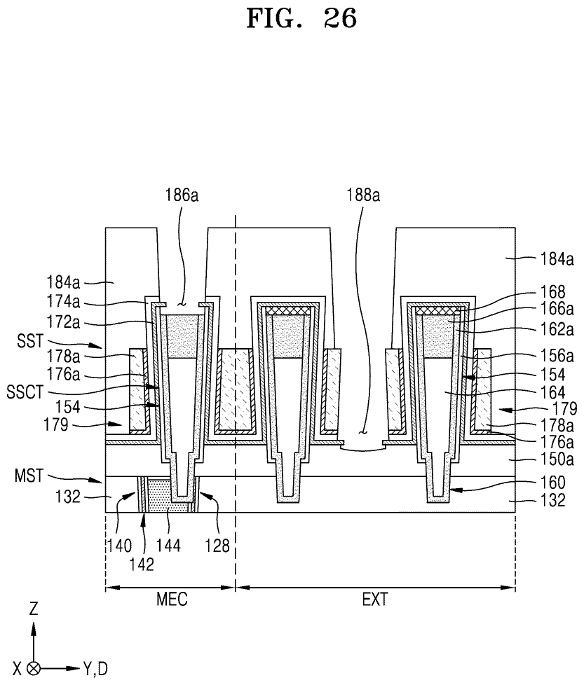

Referring to FIG. 26, the capping insulating layer 168 below the first contact hole 186 of the memory cell region MEC is further etched. Accordingly, the drain conductive layer 166a of the memory cell region MEC is exposed, and a first extended contact hole 186a having a greater diameter than the first contact hole 186 is formed. When forming the first extended contact hole 186a, the fourth insulating layer 184a and the second blocking dielectric layer 174a on the second charge storage layer 172a may be further etched.

The surface of the fourth insulating layer 184a adjacent to the second contact hole 188 of the extension region EXT and the surface of the second insulating layer 150a below the second contact hole 188 are etched to form a second extended contact hole 188a with a large diameter. The second extended contact hole 188a may partially expose the side surfaces of the second gate lines 176a and 178a.

Subsequently, as shown in FIG. 10, the bit line-conductive plugs 190 and 192 connected to the drain conductive layers 166a are formed in the first extended contact hole 186a. In addition, as illustrated in FIG. 10, the string selection line-conductive plugs 194 and 196 connected to the second gate lines 176a and 178a are formed in the second extended contact hole 188a.

As described above, in the vertical non-volatile memory device 100 according to the inventive concept, the string selection line-cut structure SSLC (or the string selection line-cut pattern 179) arranged in the memory cell region MEC and the extension region EXT is not formed through a photolithography process. Therefore, the manufacturing process may be simplified.

In addition, in the vertical non-volatile memory device 100 according to the inventive concept, the string selection lines 176a, 178a, and SSL may include a metal layer to lower the resistance and reduce the heat generated in a device. As a result, the vertical non-volatile memory device 100 according to the inventive concept may include reliable memory cells while simplifying the manufacturing process.

While the inventive concept has been particularly shown and described with reference to embodiments thereof, it will be understood that various changes in form and details may be made therein without departing from the spirit and scope of the following claims.

What is claimed is:

1. A vertical non-volatile memory device comprising:
a memory cell region; and
an extension region adjacent to the memory cell region in a first direction,
wherein the memory cell region comprises a memory stack structure,
wherein the memory stack structure comprises:
a plurality of first channel regions in channel holes, wherein the channel holes extend in a third direction and are spaced apart from each other in the first direction and a second direction, wherein the second direction and the third direction intersect the first direction;
a plurality of first gate dielectric layers that extend around respective ones of the plurality of first channel regions in plan view; and
a plurality of first gate lines that extend around respective ones of the plurality of first gate dielectric layers and are spaced apart from each other in the third direction,
wherein the memory cell region and the extension region each comprise a string selection structure in an upper portion thereof, and
wherein the string selection structure comprises:
a plurality of second channel regions in string selection line holes, wherein the string selection line holes extend in the third direction and are spaced apart from each other in the first and second directions;
a plurality of second gate dielectric layers on upper surfaces and on both side surfaces of the plurality of second channel regions; and
a plurality of second gate lines that extend around respective ones of the plurality of second gate dielectric layers in the plan view and spaced apart from each other in the second direction.

2. The vertical non-volatile memory device of claim 1, wherein the plurality of first gate lines each comprise a memory cell-word line, and the plurality of second gate lines each comprise a string selection line.

3. The vertical non-volatile memory device of claim 1, wherein the channel holes overlap the string selection line holes in the memory cell region in the plan view.

4. The vertical non-volatile memory device of claim 1, wherein respective first sidewalls of ones of the plurality of second gate lines comprise concave portions and convex portions in the first direction.

5. The vertical non-volatile memory device of claim 1, wherein the plurality of second gate lines are on respective ones of the plurality of the second channel regions, and the plurality of second gate lines are separated from each other by string selection line-cut structures that extend in the first direction and are spaced apart from each other in the second direction.

6. The vertical non-volatile memory device of claim 1, wherein the plurality of second gate lines each comprise a barrier metal layer and a gate metal layer, and upper surfaces and outermost side surfaces of second gate lines in the second direction are free of the barrier metal layer.

7. The vertical non-volatile memory device of claim 1, wherein the plurality of second gate dielectric layers between the plurality of second channel regions and the plurality of second gate lines in the second direction each comprise a second tunnel dielectric layer, a second charge storage layer, and a second blocking dielectric layer.

8. The vertical non-volatile memory device of claim 1, wherein the string selection structure comprises string selection cylinder structures comprising:
the plurality of second channel regions comprising cylinders;
buried insulating layers that at least partially fill inner spaces of the cylinders of the plurality of second channel regions; and
drain conductive layers on the buried insulating layers inside the cylinders.

9. The vertical non-volatile memory device of claim 8, wherein capping insulating layers are on respective ones of the plurality of second channel regions and on respective ones of the drain conductive layers in the string selection cylinder structures of the extension region.

10. The vertical non-volatile memory device of claim 8, wherein respective heights of upper surfaces of the plurality of second gate lines are less than respective heights of upper surfaces of the drain conductive layers, with respect to a substrate of the vertical non-volatile memory device.

11. A vertical non-volatile memory device comprising:
a memory cell region; and
an extension region adjacent to the memory cell region in a first direction,
wherein the memory cell region comprises a memory stack structure,
wherein the memory stack structure comprises:
a plurality of first channel regions in channel holes, wherein the channel holes extend in a third direction and are spaced apart from each other in the first direction and a second direction, wherein the second direction and the third direction intersect the first direction;
a plurality of first gate dielectric layers that extend around respective ones of the plurality of first channel regions in plan view; and
a plurality of first gate lines that extend around respective ones of the plurality of first gate dielectric layers and are spaced apart from each other in the third direction,
wherein the memory cell region and the extension region each comprise a string selection structure in an upper portion thereof, and
wherein the string selection structure comprises:
a plurality of second channel regions in string selection line holes, wherein the string selection line holes extend in the third direction and are spaced apart from each other in the first and second directions;
a plurality of second gate dielectric layers on upper surfaces and on both side surfaces of the plurality of second channel regions; and
a plurality of second gate lines that extend around respective ones of the plurality of second gate dielectric layers in plan view and are spaced apart from each other in the second direction, and
wherein ones of the plurality of first channel regions in the memory cell region are adjacent to respective ones of the plurality of second channel regions in the third direction, and a side surface of each of the second gate lines in the extension region is in contact with a respective one of a plurality of string selection line-conductive plugs.

12. The vertical non-volatile memory device of claim 11, wherein the channel holes overlap the string selection line holes in the memory cell region in a plan view, and
wherein ones of the plurality of string selection line-conductive plugs are between adjacent ones of the string selection line holes.

13. The vertical non-volatile memory device of claim 11, wherein respective first sidewalls of ones of the plurality of second gate lines comprise concave portions and convex portions in the first direction, and
wherein respective distances between the string selection line holes inside respective ones of the second gate lines is less than respective distances between adjacent ones of the string selection line holes.

14. The vertical non-volatile memory device of claim 11, wherein the second gate dielectric layers of the extension region extend in the second direction.

15. The vertical non-volatile memory device of claim 11, wherein the plurality of second gate dielectric layers comprise a second tunnel dielectric layer, a second charge storage layer, and a second blocking dielectric layer that are on a respective side surface of respective ones of the plurality of second channel regions.

16. The vertical non-volatile memory device of claim 11, wherein the string selection structure comprises string selection cylinder structures comprising:
the plurality of second channel regions comprising cylinders;
buried insulating layers that at least partially fill inner spaces of the cylinders of the plurality of second channel regions; and
drain conductive layers on the buried insulating layers inside the cylinders.

17. The vertical non-volatile memory device of claim 16, wherein capping insulating layers are on respective ones of the plurality of second channel regions and on respective ones of the drain conductive layers in the string selection cylinder structures of the extension region.

18. A vertical non-volatile memory device comprising:
a memory cell region; and
an extension region adjacent to the memory cell region in a first direction,
wherein the memory cell region comprises a memory stack structure,
wherein the memory stack structure comprises:
a plurality of first channel regions in channel holes, wherein the channel holes extend in a third direction and are spaced apart from each other in the first direction and a second direction, wherein the second direction and the third direction intersect the first direction;
a plurality of first gate dielectric layers that extend around respective ones of the plurality of first channel regions in plan view; and
a plurality of first gate lines that extend around respective ones of the plurality of first gate dielectric layers and spaced apart from each other in the third direction,
wherein the memory cell region and the extension region each comprise a string selection structure in an upper portion thereof, and
wherein the string selection structure comprises:
string selection cylinder structures;
a plurality of second gate dielectric layers on upper surfaces and on both side surfaces of a plurality of second channel regions; and
a plurality of second gate lines that extend around respective ones of the plurality of second gate dielectric layers in the plan view and are spaced apart from each other in the second direction,
wherein the string selection cylinder structures comprise:
the plurality of second channel regions comprising cylinders and in string selection line holes, wherein the string selection line holes extend in the third direction and are spaced apart from each other in the first and second directions;
buried insulating layers that at least partially fill inner spaces of the cylinders of the plurality of second channel regions; and
drain conductive layers on the buried insulating layers inside the cylinders, and
wherein the plurality of first channel regions in the memory cell region are electrically connected to respective ones of the plurality of second channel regions in the third direction,
wherein bit line-conductive plugs are on upper surfaces of respective ones of the drain conductive layers of the memory cell region, and
wherein a side surface of each of the second gate lines in the extension region is in contact with respective ones of a plurality of string selection line-conductive plugs.

19. The vertical non-volatile memory device of claim 18, wherein the second channel regions are insulated by a middle insulating layer on the memory stack structure.

20. The vertical non-volatile memory device of claim 18, wherein respective heights of upper surfaces of the plurality of second gate lines are less than respective heights of the upper surfaces of the drain conductive layers, with respect to a substrate of the vertical non-volatile memory device and
wherein the plurality of second gate lines each comprise a barrier metal layer and a gate conductive layer, and upper surfaces and outermost side surfaces of second gate lines in the second direction are free from the barrier metal layer.
